(19) United States
(12) Patent Application Publication
(10) Pub. No.: US 2026/0269810 A1
(43) Pub. Date: Sep. 10, 2026

(54) ACOUSTIC WAVE DEVICE

(71) Applicant: Murata Manufacturing Co., Ltd., Nagaokakyo-shi (JP)

(72) Inventor: Akira NOGUCHI, Nagaokakyo-shi (JP)

(21) Appl. No.: 19/665,423

(22) Filed: May 1, 2026

Related U.S. Application Data
(63) Continuation of application No. PCT/JP2024/038687, filed on Oct. 30, 2024.

(30) Foreign Application Priority Data
Nov. 9, 2023 (JP) 2023-191438

(51) Int. Cl. H03H 9/64; H03H 9/02; H03H 9/25

(52) U.S. Cl. CPC H03H 9/6433; H03H 9/02992; H03H 9/25

(57) ABSTRACT

An acoustic wave filter includes a longitudinally coupled resonator that includes a multilayer substrate and IDT electrodes. The multilayer substrate includes a piezoelectric layer including main surfaces opposite to each other and a metal layer coupled with one of the main surfaces of the piezoelectric layer. The IDT electrodes are located at one of the main surfaces. Each of the IDT electrodes includes electrode fingers parallel or substantially parallel to each other. In plan view of the main surfaces, the metal layer extends across adjacent ones of the electrode fingers included in one of the IDT electrodes.

### CROSS REFERENCE TO RELATED APPLICATIONS

This application claims the benefit of priority to Japanese Patent Application No. 2023-191438 filed on Nov. 9, 2023 and is a Continuation Application of PCT Application No. PCT/JP2024/038687 filed on Oct. 30, 2024. The entire contents of each application are hereby incorporated herein by reference.

### BACKGROUND OF THE INVENTION

### 1. Field of the Invention

The present invention relates to acoustic wave devices.

### 2. Description of the Related Art

Japanese Unexamined Patent Application Publication No. 2015-109622 describes a surface acoustic wave filter formed from a longitudinally coupled resonator including a substrate having a multilayer structure formed by laminating a piezoelectric film, a low acoustic velocity film, a high acoustic velocity film, and a support substrate. Japanese Unexamined Patent Application Publication No. 2015-109622 describes that a metal film disposed between the high acoustic velocity film and the support substrate can reduce a fractional bandwidth of the surface acoustic wave filter.

### SUMMARY OF THE INVENTION

However, in the surface acoustic wave filter described in Japanese Unexamined Patent Application Publication No. 2015-109622, attenuation characteristics degrade due to unwanted electric field distribution generated in the piezoelectric film.

Example embodiments of the present invention provide acoustic wave devices each including a longitudinally coupled resonator with reduced degradation of attenuation characteristics.

An acoustic wave device according to an example embodiment of the present invention includes a longitudinally coupled resonator including a piezoelectric substrate and a plurality of interdigital transducer (IDT) electrodes, wherein the piezoelectric substrate includes a piezoelectric layer including a first main surface and a second main surface opposite each other, the plurality of IDT electrodes being located at the first main surface, and a metal layer coupled with the second main surface of the piezoelectric layer, each of the plurality of IDT electrodes includes a plurality of electrode fingers parallel or substantially parallel to each other, and in plan view of the first main surface and the second main surface, the metal layer extends across adjacent ones of the plurality of electrode fingers included in one of the plurality of IDT electrodes.

Example embodiments of the present invention provide acoustic wave devices each including a longitudinally coupled resonator with reduced degradation of attenuation characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit structure diagram of an acoustic wave filter according to an example embodiment of the present invention.

FIG. 2 is an electrode structure diagram of a longitudinally coupled resonator according to an example embodiment of the present invention.

FIGS. 3A and 3B includes a plan view and a cross-sectional view of an acoustic wave filter according to an example embodiment of the present invention.

FIG. 4 is a cross-sectional view of an acoustic wave filter according to a comparative example.

FIG. 5 is a graph describing passband characteristics of acoustic wave filters according to an example embodiment and a comparative example.

FIG. 6A is a schematic cross-sectional view describing electric field distribution in a piezoelectric layer of an acoustic wave filter according to a comparative example.

FIG. 6B is a schematic cross-sectional view describing electric field distribution in a piezoelectric layer of an acoustic wave filter according to an example embodiment of the present invention.

FIGS. 7A and 7B includes a plan view and a cross-sectional view of an acoustic wave filter according to a first modification example of an example embodiment of the present invention.

FIG. 8 is a plan view of an acoustic wave filter according to a second modification example of an example embodiment of the present invention.

### DETAILED DESCRIPTION OF THE EXAMPLE EMBODIMENTS

Example embodiments of the present disclosure are described below in detail with reference to the drawings. The example embodiments described below are comprehensive or specific examples. Characteristics such as numerical values, shapes, materials, components, arrangement of the components, and connection between the components described in the example embodiments below are mere examples, and are not intended to limit the present invention. Among components described in the example embodiments below, components not described in independent claims are optional. The dimensions or the ratios between the dimensions of components described in the drawings are not necessarily precise.

Each of the drawings is a schematic diagram drawn with enhancement, omission, or adjustment in ratio as appropriate to illustrate example embodiments of the present invention. Each drawing is not necessarily precisely drawn, and may be different from the actual structure in terms of shapes, positional relationship, and ratios. In each drawing, substantially the same components are denoted with the same reference signs, and redundant description may be omitted or simplified.

Regarding disposition of a component in the present disclosure, the expression “a component is disposed at a substrate” includes a case in which the component extends over a main surface of the substrate, and a case in which the component is disposed in the substrate. In addition to a case in which the component is disposed on the main surface of the substrate while being in contact with the main surface, the expression “a component is disposed over a main surface of a substrate” includes a case in which the component is disposed above the main surface without being in contact with the main surface (for example, a case in which the component is laminated on another component that is disposed in contact with the main surface). In addition, the expression “a component is disposed over a main surface of a substrate” may also include a case in which the component is disposed in a recess formed in the main surface of the substrate. The expression “a component is disposed in a substrate” includes a case in which the entirety of the component is disposed between two main surfaces of the substrate with a portion of the component not covered with the substrate and a case in which only a portion of the component is disposed in the substrate, in addition to a case in which the component is encapsulated in a module substrate.

In component disposition in the description of example embodiments of the present disclosure, the expression “an A layer is coupled with a B layer” refers to a case in which the A layer and the B layer are in contact with each other with no layer, other than an adhesive layer, interposed therebetween.

In the circuit structure in the present disclosure, the expression “being connected” includes a case of being electrically connected via a matching element such as an inductor or a capacitor, and a switch circuit, in addition to a case of being directly connected with an electrode and/or a wiring conductor. The expression “being connected between A and B” refers to a case of being connected to both A and B between A and B.

Terms indicating relationships between elements, such as “parallel” and “perpendicular”, terms indicating shapes of elements, such as “rectangular”, and numerical ranges are not intended to be limited to their strict meanings, but are intended to include substantially equivalent ranges, for example, including an error of several percent.

In the example embodiments described below, a filter pass band is defined as a frequency bandwidth between two frequencies, or from a minimum value of insertion loss in the pass band to a frequency about 3 dB higher than the minimum value, for example, within manufacturing or measurement tolerances.

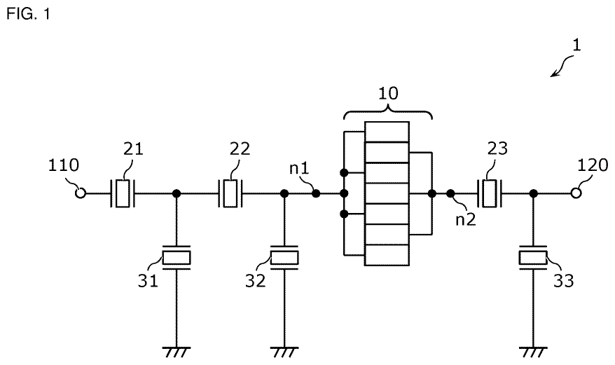

First, a circuit structure of an acoustic wave filter 1 according to an example embodiment is described. FIG. 1 is a circuit structure diagram of the acoustic wave filter 1 according to the present example embodiment. As illustrated in the drawing, the acoustic wave filter 1 is an example of an acoustic wave device, and includes a longitudinally coupled resonator 10, series-arm resonators 21, 22, and 23, and parallel-arm resonators 31, 32, and 33.

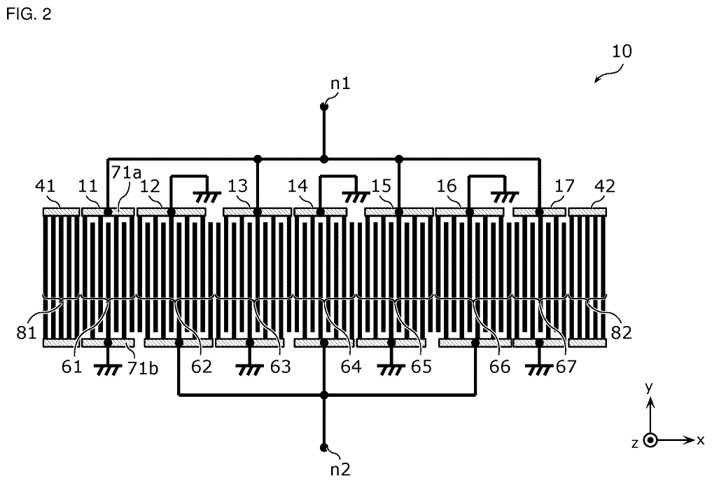

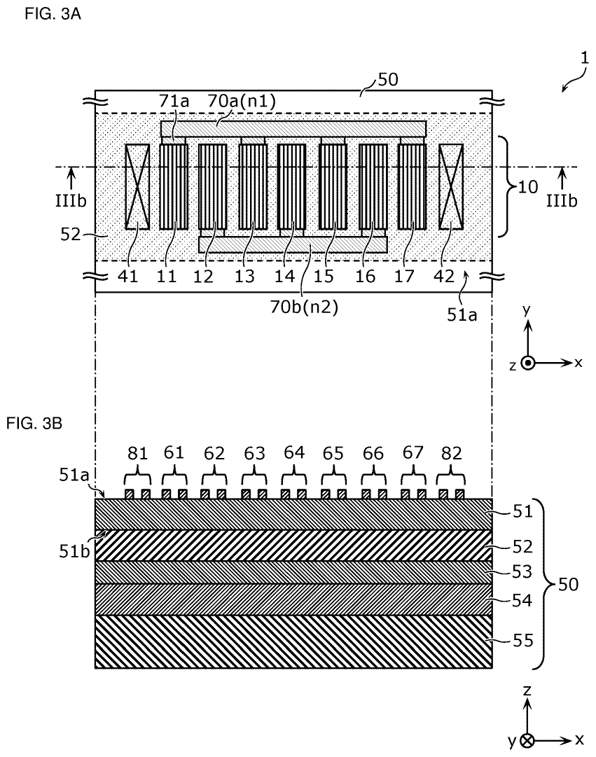

The longitudinally coupled resonator 10 includes, for example, seven acoustic wave resonators. Each of the seven acoustic wave resonators includes an interdigital transducer (IDT) electrode disposed at a multilayer substrate 50. A specific structure of the longitudinally coupled resonator 10 is described with reference to FIG. 2 and FIGS. 3A and 3B.

The series-arm resonators 21 and 22 are disposed on a series-arm path connecting an input/output terminal 110 and the longitudinally coupled resonator 10. The series-arm resonator 23 is disposed on a series-arm path connecting an input/output terminal 120 and the longitudinally coupled resonator 10. The parallel-arm resonator 31 is connected between the ground and a node between the series-arm resonators 21 and 22. The parallel-arm resonator 32 is connected between the ground and a node between the series-arm resonator 22 and the longitudinally coupled resonator 10. The parallel-arm resonator 33 is connected between the ground and a node between the series-arm resonator 23 and the input/output terminal 120.

With the above connection structure, the acoustic wave filter 1 functions as a band-pass filter. The longitudinally coupled resonator 10 defines a basic pass band and an attenuation band of the acoustic wave filter 1, and the series-arm resonators 21 to 23 and the parallel-arm resonators 31 to 33 contribute to fine adjustment of a pass-band width, steepness adjustment at a pass band end portion, and formation of an attenuation pole in the attenuation band.

The acoustic wave filter 1 according to the present example embodiment may be any acoustic wave filter that includes at least the longitudinally coupled resonator 10. The number of acoustic wave resonators included in the longitudinally coupled resonator 10 is not limited to seven, and may be two or more. Any number of series-arm resonators and parallel-arm resonators may be connected to the longitudinally coupled resonator 10, and the series-arm resonators and the parallel-arm resonator may be connected to the longitudinally coupled resonator 10 in any method. The number and the connection structure are determined in accordance with passband characteristics that the acoustic wave filter 1 is required to have.

FIG. 2 is an electrode structure diagram of the longitudinally coupled resonator 10 according to the present example embodiment. FIG. 2 is a diagram of an electrode structure of IDT electrodes 11 to 17 included in the seven acoustic wave resonators included in the longitudinally coupled resonator 10, and reflecting electrodes 41 and 42. The longitudinally coupled resonator 10 includes the IDT electrodes 11, 12, 13, 14, 15, 16, and 17 and the reflecting electrodes 41 and 42. The IDT electrodes and the reflecting electrodes illustrated in FIG. 2 are used to illustrate a typical structure of an acoustic wave resonator forming the longitudinally coupled resonator 10. Thus, for example, the number and the length of electrode fingers included in the IDT electrodes and the reflecting electrodes are not limited to those illustrated in FIG. 2.

As illustrated in FIG. 2, the IDT electrode 11 includes multiple electrode fingers 61, and busbar electrodes 71a and 71b.

The multiple electrode fingers 61 are parallel or substantially parallel to each other, and extend in a direction (y-axis direction) perpendicular to an acoustic wave propagation direction (x-axis direction). The electrode fingers 61 connected to the busbar electrode 71a and the electrode fingers 61 connected to the busbar electrode 71b interdigitate with each other.

The busbar electrode 71a connects the first ends of a subset of the multiple electrode fingers 61. The busbar electrode 71b connects the first ends of another subset of the multiple electrode fingers 61. The busbar electrodes 71a and 71b extend in a direction intersecting with an extension direction (y-axis direction) of the multiple electrode fingers 61. The busbar electrode 71a and the busbar electrode 71b face each other with the multiple electrode fingers 61 interposed therebetween.

As in the IDT electrode 11, each of the IDT electrodes 12 to 17 also includes a pair of busbar electrodes and multiple electrode fingers between the pair of busbar electrodes. The IDT electrode 12 includes multiple electrode fingers 62, the IDT electrode 13 includes multiple electrode fingers 63, the IDT electrode 14 includes multiple electrode fingers 64, the IDT electrode 15 includes multiple electrode fingers 65, the IDT electrode 16 includes multiple electrode fingers 66, and the IDT electrode 17 includes multiple electrode fingers 67.

The reflecting electrode 41 includes multiple reflecting electrode fingers 81, and a pair of busbar electrodes. The reflecting electrode 42 includes multiple reflecting electrode fingers 82, and a pair of busbar electrodes. The multiple reflecting electrode fingers 81 and 82 are parallel or substantially parallel to each other, and extend in a direction (y-axis direction) perpendicular to the acoustic wave propagation direction (x-axis direction). Each of the multiple reflecting electrode fingers 81 is connected to a pair of busbar electrodes, and the pair of busbar electrodes are opposite each other with the multiple reflecting electrode fingers interposed therebetween. Each of the multiple reflecting electrode fingers 82 is connected to the pair of busbar electrodes, and the pair of busbar electrodes are opposite each other with the multiple reflecting electrode fingers interposed therebetween.

The IDT electrodes 11 to 17 and the reflecting electrodes 41 and 42 are arranged in the acoustic wave propagation direction (x-axis direction) in order of the reflecting electrode 41, the IDT electrode 11, 12, 13, 14, 15, 16, 17, and the reflecting electrode 42. More specifically, the longitudinally coupled resonator 10 has a structure in which multiple IDT electrodes are arranged adjacent to each other in the acoustic wave propagation direction.

In the arrangement structure of the IDT electrodes 11 to 17, busbar electrodes of the IDT electrodes 11, 13, 15, and 17 located in the positive y-axis direction are connected to an input-output node n1 serving as a hot terminal. Busbar electrodes of the IDT electrodes 11, 13, 15, and 17 located in the negative y-axis direction are connected to the ground. Busbar electrodes of the IDT electrodes 12, 14, and 16 located in the negative y-axis direction are connected to an input-output node n2 serving as a hot terminal. Busbar electrodes of the IDT electrodes 12, 14, and 16 located in the positive y-axis direction are connected to the ground.

Electrode parameters of the IDT electrodes included in the longitudinally coupled resonator 10 are described.

An electrode-finger pitch of the IDT electrode 11 is defined as a repetition cycle of the multiple electrode fingers 61. The electrode-finger pitch is defined as (W+S), where a line width of the electrode fingers 61 is denoted with W, and a space width between two adjacent electrode fingers 61 is denoted with S. A wavelength λ is defined as two times of the electrode-finger pitch. The duty of the IDT electrode 11 refers to line width occupancy of the multiple electrode fingers 61, or a rate of the line width of the multiple electrode fingers 61 with respect to the sum of the line width and the space width, and is defined as W/(W+S). The cross width of the IDT electrode 11 is a length of an overlapping portion of the electrode fingers when the electrode fingers 61 connected to the busbar electrode 71a and the electrode fingers 61 connected to the busbar electrode 71b are viewed in the acoustic wave propagation direction (x-axis direction).

Table 1 lists electrode parameters of the IDT electrodes and the reflecting electrodes included in the longitudinally coupled resonator 10.

TABLE 1

| LONGITUDINALLY | | | | | | |
|---|---|---|---|---|---|---|
| COUPLED RESONATOR | | NUMBER | WAVELENGTH | | CROSS | INTERELECTRODE |
| 10, 10A, 10B | | OF PAIRS | (μm) | DUTY | WIDTH (μm) | GAP (μm) |
| REFLECTING ELECTRODE | | 10.5 | 4.163 | 0.6 | 147.57 | 0.5014 |
| 41 | | | | | | |
| IDT | MAIN | 13 | 4.187 | ↑ | ↑ | 0.4864 |
| ELECTRODE | NARROW | 2.5 | 3.913 | ↑ | ↑ | 0.4677 |
| 11 | PITCH | | | | | |
| IDT | NARROW | 2.5 | 3.876 | ↑ | ↑ | 0.4865 |
| ELECTRODE | PITCH | | | | | |
| 12 | MAIN | 9 | 4.226 | ↑ | ↑ | 0.4867 |
| | NARROW | 2.5 | 3.879 | ↑ | ↑ | 0.4672 |
| | PITCH | | | | | |
| IDT | NARROW | 2.5 | 3.902 | ↑ | ↑ | 0.4857 |
| ELECTRODE | PITCH | | | | | |
| 13 | MAIN | 14 | 4.187 | ↑ | ↑ | 0.4864 |
| | NARROW | 2.5 | 3.913 | ↑ | ↑ | 0.4679 |
| | PITCH | | | | | |
| IDT | NARROW | 2.5 | 3.879 | ↑ | ↑ | 0.4864 |
| ELECTRODE | PITCH | | | | | |
| 14 | MAIN | 6 | 4.221 | ↑ | ↑ | 0.4868 |
| | NARROW | 2.5 | 3.885 | ↑ | ↑ | 0.4682 |
| | PITCH | | | | | |
| IDT | NARROW | 2.5 | 3.912 | ↑ | ↑ | 0.4860 |
| ELECTRODE | PITCH | | | | | |
| 15 | MAIN | 9 | 4.182 | ↑ | ↑ | 0.4854 |
| | NARROW | 2.5 | 3.902 | ↑ | ↑ | 0.4679 |
| | PITCH | | | | | |
| IDT | NARROW | 2.5 | 3.890 | ↑ | ↑ | 0.4860 |
| ELECTRODE | PITCH | | | | | |
| 16 | MAIN | 12 | 4.203 | ↑ | ↑ | 0.4857 |
| | NARROW | 2.5 | 3.885 | ↑ | ↑ | 0.4675 |
| | PITCH | | | | | |
| IDT | NARROW | 2.5 | 3.90 | ↑ | ↑ | 0.4861 |
| ELECTRODE | PITCH | | | | | |
| 17 | MAIN | 15 | 4.194 | ↑ | ↑ | 0.5013 |

| | | | | |
|---|---|---|---|---|
| REFLECTING ELECTRODE | 10.5 | 4.154 | ↑ | ↑ |
| 42 | | | | |

As illustrated in Table 1, each of the IDT electrodes 11 to 17 according to the present example embodiment includes multiple separate areas with different electrode-finger pitches. More specifically, each of the IDT electrodes 11 to 17 is divided into a main area having a major electrode-finger pitch of the IDT electrode, and one or more narrow pitch areas having an electrode-finger pitch smaller than the electrode-finger pitch of the main area.

In the separate areas of each IDT electrode, when the intervals between adjacent electrode fingers are not uniform, the electrode-finger pitch in each separate area is defined as a mean electrode-finger pitch in the separate area. The mean electrode-finger pitch in each separate area is defined as Di/(Ni−1), where the total number of electrode fingers included in the separate area is denoted by Ni, and a center-to-center distance, in the separate area, between the electrode finger located at a first end in the acoustic wave propagation direction and the electrode finger located at a second end in the acoustic wave propagation direction is denoted by Di.

Alternatively, each of the multiple IDT electrodes 11 to 17 included in the longitudinally coupled resonator 10 may be simply formed from a single area with a uniform electrode-finger pitch.

The structure of the acoustic wave filter 1 according to the present example embodiment is described now. FIGS. 3A and 3B include a plan view and a cross-sectional view of the acoustic wave filter 1 according to the present example embodiment. FIG. 3A is a diagram of a main surface 51a (first main surface) of a piezoelectric layer 51 included in the acoustic wave filter 1, viewed from the side in the positive z-axis direction. FIG. 3A also illustrates a metal layer 52 coupled with a main surface 51b (second main surface) of the piezoelectric layer 51, as viewed through the piezoelectric layer 51. FIG. 3B is a cross-sectional view taken along line IIIb-IIIb in FIG. 3A. For convenience, FIG. 3B illustrates two electrode fingers (pair of electrode fingers) for each IDT electrode, but each of the actual IDT electrodes 11 to 17 includes three or more electrode fingers. In addition, for convenience, FIG. 3B illustrates two reflecting electrode fingers (pair of reflecting electrode fingers) for each reflecting electrode, but each of the actual reflecting electrodes 41 and 42 may include three or more reflecting electrode fingers.

As illustrated in FIG. 3A, the longitudinally coupled resonator 10 includes the multilayer substrate 50, the multiple IDT electrodes 11 to 17, and the reflecting electrodes 41 and 42. The longitudinally coupled resonator 10 does not have to include the reflecting electrodes 41 and 42. Unlike in FIG. 2 in which the electrode fingers and reflecting electrode fingers are drawn in detail, FIG. 3A illustrates the IDT electrodes 11 to 17 and the reflecting electrodes 41 and 42 with simplified marks.

As illustrated in FIG. 3A, busbar electrodes of the IDT electrodes 11, 13, 15, and 17 located in the positive y-axis direction are connected in common to a connection wire 70a (corresponding to an input-output node n1) serving as a hot terminal. Busbar electrodes of the IDT electrodes 12, 14, and 16 located in the negative y-axis direction are connected in common to a connection wire 70b (corresponding to an input-output node n2) serving as a hot terminal. In FIG. 3A, busbar electrodes in the IDT electrodes 11 to 17 connected to the ground in the IDT electrodes 11 to 17 and the ground connection structure are not illustrated.

As illustrated in FIG. 3B, the multilayer substrate 50 is an example of a piezoelectric substrate, and includes a piezoelectric layer 51, a metal layer 52, a low-acoustic-velocity layer 53, a high-acoustic-velocity layer 54, and a support substrate 55. The multilayer substrate 50 is a substrate including the piezoelectric layer 51 and having piezoelectricity.

The piezoelectric layer 51 includes a main surface 51a (first main surface) and a main surface 51b (second main surface) opposite each other, and the IDT electrodes 11 to 17 and the reflecting electrodes 41 and 42 are located at the main surface 51a. For example, lithium tantalate (LiTaO₃) may be used for the piezoelectric layer 51. The film thickness of the piezoelectric layer 51 is, for example, 900 nm.

The metal layer 52 is coupled with the main surface 51b of the piezoelectric layer 51. As illustrated in FIG. 3A, in plan view of the main surfaces 51a and 51b of the piezoelectric layer 51, the metal layer 52 overlaps the entire areas of the multiple IDT electrodes 11 to 17.

For example, titanium (Ti) may be used for the metal layer 52. The film thickness of the metal layer 52 is, for example, about 50 nm. The metal layer 52 may include an alloy including multiple metal materials, or a multilayer body including multiple layers including different metal materials. In addition, an adhesive layer may be interposed between the metal layer 52 and the piezoelectric layer 51 to ensure strength to bond these layers.

The adhesive layer is a dielectric layer with a thickness less than or equal to about 1/10 of the thickness of the piezoelectric layer 51, within manufacturing or measurement tolerances, for example, formed from epoxy resin.

The support substrate 55 is located farthest from the IDT electrodes 11 to 17 in the multilayer substrate 50. The support substrate 55, the metal layer 52, and the piezoelectric layer 51 are laminated in this order. For example, silicon (Si) is usable for the support substrate 55. The thickness of the support substrate 55 is, for example, about 125 pam, within manufacturing or measurement tolerances.

The low-acoustic-velocity layer 53 is disposed between the metal layer 52 and the support substrate 55, and bulk waves propagate through the low-acoustic-velocity layer 53 at a lower acoustic velocity than bulk waves that propagate through the piezoelectric layer 51. With this structure and the characteristics of acoustic waves whose energy is concentrated in a medium with an intrinsically low acoustic velocity, leakage of surface acoustic wave energy out of the piezoelectric layer 51 can be reduced. The low-acoustic-velocity layer 53 may include, for example, a dielectric material such as silicon oxide (SiO₂), glass, silicon oxynitride, lithium oxide, tantalum oxide, or a compound obtained by adding fluorine, carbon, or boron to silicon oxide, or a material including any of the above materials as a main component. The film thickness of the low-acoustic-velocity layer 53 is, for example, about 300 nm, within manufacturing or measurement tolerances.

The high-acoustic-velocity layer 54 is disposed between the low-acoustic-velocity layer 53 and the support substrate 55, and bulk waves propagate through the high-acoustic-velocity layer 54 at a higher acoustic velocity than bulk waves that propagate through the piezoelectric layer 51. The high-acoustic-velocity layer 54 may include, for example, piezoelectric materials such as silicon nitride (SiN), aluminum nitride, lithium tantalate, lithium niobate, and quartz, ceramics such as alumina, sapphire, magnesia, silicon carbide, zirconia, cordierite, mullite, steatite, and forsterite, dielectrics such as diamond and glass, semiconductors such as silicon and gallium nitride, resins, or materials mainly including the above materials. The film thickness of the high-acoustic-velocity layer 54 is, for example, about 300 nm, within manufacturing or measurement tolerances.

In the multilayer structure of the multilayer substrate 50, compared to an existing structure using a substrate simply formed from a piezoelectric material, that is, a piezoelectric single-layer substrate, q-values of an acoustic wave resonator in resonant frequency and antiresonant frequency can be significantly increased. More specifically, an acoustic wave resonator with high q-values can be formed, and thus an acoustic wave filter with a reduced insertion loss can be formed by using the acoustic wave resonator.

Alternatively, the high-acoustic-velocity layer 54 and the support substrate 55 may be combined to provide a single high-acoustic-velocity support substrate. The high-acoustic-velocity support substrate supports the IDT electrodes 11 to 17, the piezoelectric layer 51, the metal layer 52, and the low-acoustic-velocity layer 53. The high-acoustic-velocity support substrate allows bulk waves to propagate therethrough at a higher acoustic velocity than acoustic waves, such as surface waves and boundary waves, that propagate through the piezoelectric layer 51, and confines the surface acoustic waves in a portion where the piezoelectric layer 51 and the low-acoustic-velocity layer 53 are laminated to prevent the surface acoustic waves from leaking downward below the high-acoustic-velocity support substrate. The high-acoustic-velocity support substrate may include, for example, piezoelectric materials such as aluminum nitride, lithium tantalate, lithium niobate, and quartz, ceramics such as alumina, sapphire, magnesia, silicon nitride, silicon carbide, zirconia, cordierite, mullite, steatite, forsterite, spinel, and sialon, dielectrics such as aluminum oxide, silicon oxynitride, diamond-like carbon (DLC), and diamond, semiconductors such as silicon, or materials mainly including the above materials. Spinel described above includes an aluminum compound including oxygen and one or more elements selected from the group including Mg, Fe, Zn, and Mn. Examples of spinel include MgAl₂O₄, FeAl₂O₄, ZnAl₂O₄, and MnAl₂O₄.

Herein, “the main component in the material” refers to the component that accounts for more than 50 weight percent of the material. The main component may be in a monocrystalline, polycrystalline, or amorphous state, or in a mixed state including these forms.

The piezoelectric substrate according to the present example embodiment may have a structure in which a support substrate 55, an energy confining layer, a metal layer 52, and a piezoelectric layer 51 are laminated in this order, instead of the multilayer substrate 50. In this case, the IDT electrodes 11 to 17 and the reflecting electrodes 41 and 42 are disposed over the piezoelectric layer 51.

The energy confining layer includes one or more layers, and bulk acoustic waves propagate through the at least one layer at a higher velocity than acoustic waves that propagate near the piezoelectric layer 51. For example, the energy confining layer may have a multilayer structure including a low-acoustic-velocity layer and a high-acoustic-velocity layer. The low-acoustic-velocity layer allows bulk waves to propagate through the low-acoustic-velocity layer at a lower acoustic velocity than acoustic waves that propagate through the piezoelectric layer 51. The high-acoustic-velocity layer allows bulk waves to propagate through the high-acoustic-velocity layer at a higher acoustic velocity than acoustic waves that propagate through the piezoelectric layer 51. The support substrate 55 may be used as a high-acoustic-velocity layer.

The energy confining layer may be an acoustic impedance layer in which low acoustic impedance layers having a relatively low acoustic impedance and high acoustic impedance layers having a relatively high acoustic impedance are alternately laminated.

Instead of the multilayer substrate 50, the piezoelectric substrate according to the present example embodiment may include the support substrate 55, the metal layer 52, and the piezoelectric layer 51 laminated in this order, without including the low-acoustic-velocity layer 53 and the high-acoustic-velocity layer 54.

Now, the structure of the electrode fingers included in the IDT electrodes 11 to 17 and the structure of the reflecting electrode fingers included in the reflecting electrodes 41 and 42 are described.

The electrode fingers included in the IDT electrodes 11 to 17 and the reflecting electrode fingers included in the reflecting electrodes 41 and 42 have, for example, a multilayer structure including a close adhesion layer and a main electrode layer.

The main electrode layer includes, for example, aluminum (Al) as a main component, and has a film thickness of, for example, about 100 nm. The close adhesion layer is disposed between the main electrode layer and the piezoelectric layer 51, and improves the degree of adhesion of the main electrode layer to the multilayer substrate 50. The close adhesion layer includes, for example, titanium (Ti), and has a film thickness of, for example, 10 nm, within manufacturing or measurement tolerances. The structures of the IDT electrodes 11 to 17 and the reflecting electrodes 41 and 42 are not limited to the multilayer structure described above, and the IDT electrodes 11 to 17 and the reflecting electrodes 41 and 42 may include, for example, metal such as Ti, Al, Cu, Pt, Au, Ag, or Pd or an alloy, or may include multiple multilayer bodies including the above metal or alloy.

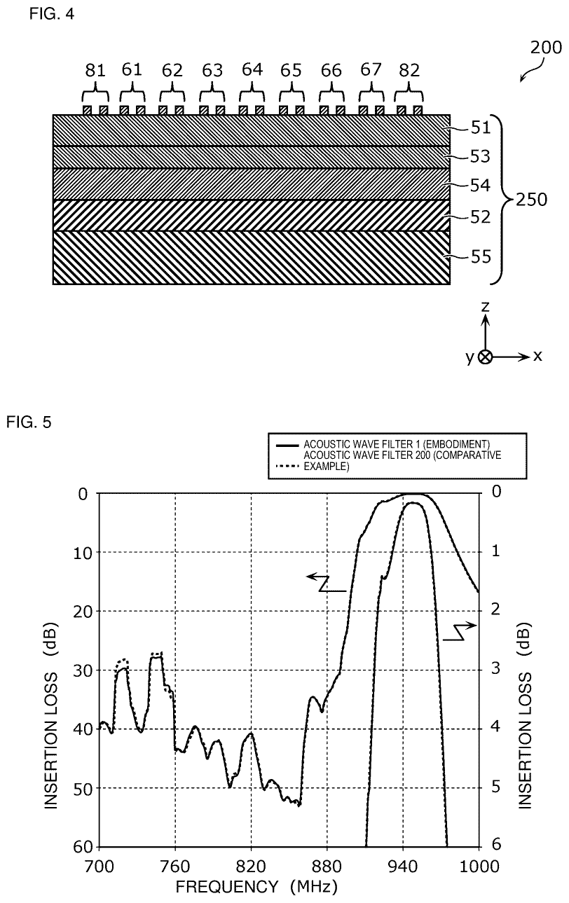

The structure of an acoustic wave filter 200 according to a comparative example is described now. FIG. 4 is a cross-sectional view of the acoustic wave filter 200 according to the comparative example. As illustrated in FIG. 4, the acoustic wave filter 200 includes a multilayer substrate 250, multiple IDT electrodes 11 to 17 (illustrated as electrode fingers 61 to 67 in FIG. 4), and reflecting electrodes 41 and 42 (illustrated as reflecting electrode fingers 81 and 82 in FIG. 4). The acoustic wave filter 200 according to the comparative example differs from the acoustic wave filter 1 according to the present example embodiment in terms of the multilayer structure of the multilayer substrate 250. Hereafter, the acoustic wave filter 200 according to the comparative example is mainly described in terms of the structure of the multilayer substrate 250 that is different from the structure in the acoustic wave filter 1 according to the example embodiment.

As illustrated in FIG. 4, the multilayer substrate 250 includes a piezoelectric layer 51, a low-acoustic-velocity layer 53, a high-acoustic-velocity layer 54, a metal layer 52, and a support substrate 55. The piezoelectric layer 51, the low-acoustic-velocity layer 53, the high-acoustic-velocity layer 54, the metal layer 52, and the support substrate 55 are laminated in this order from the side in the positive z-axis direction. More specifically, the metal layer 52 is disposed between the support substrate 55 and the high-acoustic-velocity layer 54 without being coupled with the piezoelectric layer 51.

The passband characteristics of the acoustic wave filter 1 according to the present example embodiment are then described. FIG. 5 is a graph describing the passband characteristics of acoustic wave filters according to the present example embodiment and the comparative example. As illustrated in FIG. 5, when the passband characteristics of the acoustic wave filter 1 according to the present example embodiment and the passband characteristics of the acoustic wave filter 200 according to the comparative example are compared, the passband characteristics have no difference around the pass band. In contrast, in the attenuation band (for example, about 700 MHz to about 760 MHz) lower than the pass band, the acoustic wave filter 1 according to the present example embodiment has higher attenuation (has a greater minimum value in insertion loss) than the acoustic wave filter 200 according to the comparative example. In other words, the degradation of the attenuation characteristics is further reduced in the acoustic wave filter 1 according to the present example embodiment than in the acoustic wave filter 200 according to the comparative example.

Hereafter, the cause for further reduction of the degradation of attenuation characteristics in the acoustic wave filter 1 according to the present example embodiment than in the acoustic wave filter 200 according to the comparative example is described.

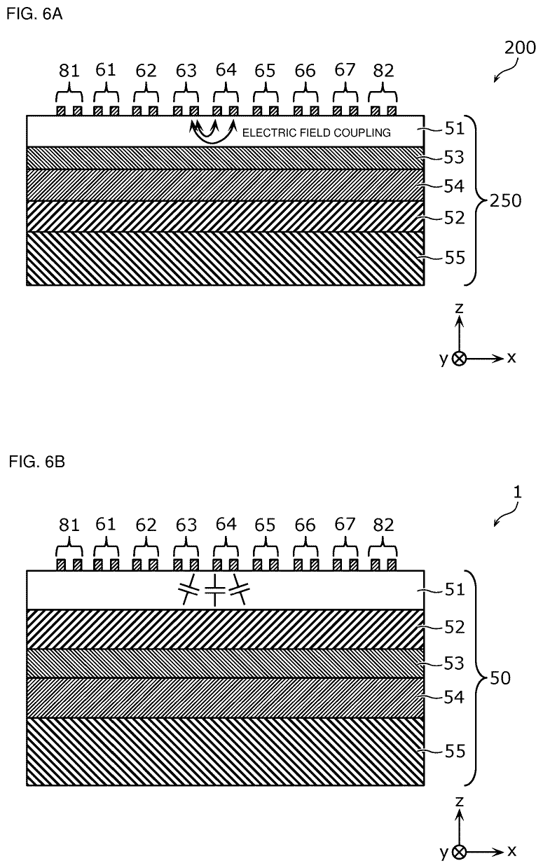

FIG. 6A is a schematic cross-sectional view describing electric field distribution in the piezoelectric layer 51 of the acoustic wave filter 200 according to the comparative example. In the piezoelectric substrate including the piezoelectric layer, the low-acoustic-velocity layer, the high-acoustic-velocity layer, and the support substrate, the piezoelectric layer having a highest dielectric constant has high electric field density. Thus, as illustrated in FIG. 6A, unused electric field coupling occurs between two adjacent IDT electrodes, and between an IDT electrode and a reflecting electrode adjacent to each other. Thus, unused resonator coupling occurs between multiple acoustic wave resonators included in the longitudinally coupled resonator, and attenuation characteristics of the acoustic wave filter 200 thus degrade.

FIG. 6B is a schematic cross-sectional view describing electric field distribution in the piezoelectric layer 51 of the acoustic wave filter 1 according to the present example embodiment. As illustrated in FIG. 6B, the metal layer 52 coupled with the main surface 51b of the piezoelectric layer 51 is capacitively coupled with the electrode fingers included in each IDT electrode, and the capacitive coupling provides a charge path from each electrode finger to the metal layer 52. More specifically, the metal layer 52 coupled with the main surface 51b of the piezoelectric layer 51 provides a charge path, and reduces unused electric field coupling that would occur between two adjacent IDT electrodes, and between an IDT electrode and a reflecting electrode adjacent to each other. Thus, due to the metal layer 52, the acoustic wave filter 1 according to the present example embodiment effectively reduces electric field coupling between IDT electrodes and between an IDT electrode and a reflecting electrode included in the longitudinally coupled resonator 10, and can thus reduce degradation of attenuation characteristics.

In the acoustic wave filter 1 according to the present example embodiment, the metal layer 52 may be connected to the ground.

The acoustic wave filter 1 with this structure can release unused electric field that occurs in the piezoelectric layer 51 to the ground through the metal layer 52, and thus can reduce degradation of attenuation characteristics.

In the acoustic wave filter 1 according to the present example embodiment, in plan view of the main surfaces 51a and 51b of the piezoelectric layer 51, the metal layer 52 does not have to overlap the entire areas of the multiple IDT electrodes 11 to 17, and may extend across any two adjacent electrode fingers in the IDT electrodes 11 to 17.

In the acoustic wave filter 1 with this structure, the metal layer 52 faces the two adjacent electrode fingers in plan view. Thus, charge paths from the two electrode fingers to the metal layer 52 are provided, and unused electric field coupling that would occur between the two electrode fingers can be reduced. Thus, the acoustic wave filter can reduce degradation of attenuation characteristics.

An acoustic wave filter 1A according to a first modification example of an example embodiment of the present disclosure is described now. The acoustic wave filter 1A according to the present modification example is an example of an acoustic wave device, and includes a longitudinally coupled resonator 10A, series-arm resonators 21, 22, and 23, and parallel-arm resonators 31, 32, and 33. The acoustic wave filter 1A according to the present modification example differs from the acoustic wave filter 1 according to the present example embodiment simply in terms of the structure of the longitudinally coupled resonator 10A. Hereafter, the acoustic wave filter 1A according to the present modification example is mainly described in terms of a different structure, and descriptions of the same components as those in the acoustic wave filter 1 according to the present example embodiment are omitted.

The longitudinally coupled resonator 10A includes seven acoustic wave resonators. Each of the seven acoustic wave resonators includes IDT electrodes disposed at a multilayer substrate 50A. The structures of the IDT electrodes and reflecting electrodes included in the seven acoustic wave resonators are the same as the structures of the IDT electrodes and the reflecting electrodes included in the longitudinally coupled resonator 10, and the electrode parameters are the same as those listed in Table 1.

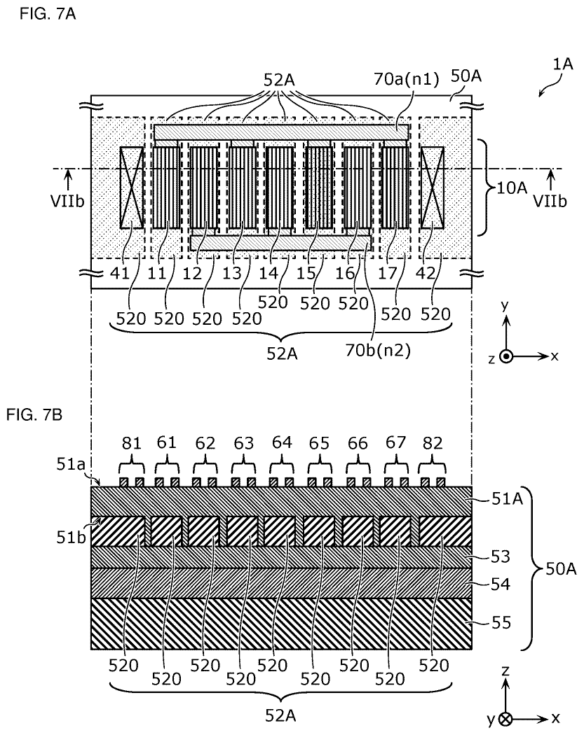

FIGS. 7A and 7B includes a plan view and a cross-sectional view of the acoustic wave filter 1A according to the first modification example of the above-described example embodiment. FIG. 7A is a diagram of a main surface 51a (first main surface) of a piezoelectric layer 51A included in the acoustic wave filter 1A, viewed from the side in the positive z-axis direction. FIG. 7A also illustrates a metal layer 52A coupled with a main surface 51b (second main surface) of the piezoelectric layer 51A, as viewed through the piezoelectric layer 51A. FIG. 7B is a cross-sectional view taken along line VIIb-VIIb in FIG. 7A. For convenience, FIG. 7B illustrates two electrode fingers (pair of electrode fingers) for each IDT electrode, but each of the actual IDT electrodes 11 to 17 includes three or more electrode fingers. In addition, for convenience, FIG. 7B illustrates two reflecting electrode fingers (pair of reflecting electrode fingers) for each reflecting electrode, but each of the actual reflecting electrodes 41 and 42 may include three or more reflecting electrode fingers.

As illustrated in FIG. 7A, the longitudinally coupled resonator 10A includes the multilayer substrate 50A, the multiple IDT electrodes 11 to 17, and the reflecting electrodes 41 and 42. The longitudinally coupled resonator 10A does not have to include the reflecting electrodes 41 and 42. Unlike in FIG. 2 in which the electrode fingers and reflecting electrode fingers are drawn in detail, FIG. 7A illustrates the IDT electrodes 11 to 17 and the reflecting electrodes 41 and 42 with simplified marks.

As illustrated in FIG. 7A, busbar electrodes of the IDT electrodes 11, 13, 15, and 17 located in the positive y-axis direction are connected in common to a connection wire 70a (corresponding to an input-output node n1) serving as a hot terminal. Busbar electrodes of the IDT electrodes 12, 14, and 16 located in the negative y-axis direction are connected in common to a connection wire 70b (corresponding to an input-output node n2) serving as a hot terminal. In FIG. 7A, the ground connection structure in the IDT electrodes 11 to 17 is not illustrated.

As illustrated in FIG. 7B, the multilayer substrate 50A is an example of a piezoelectric substrate having piezoelectricity, and includes a piezoelectric layer 51A, a metal layer 52A, a low-acoustic-velocity layer 53, a high-acoustic-velocity layer 54, and a support substrate 55.

The piezoelectric layer 51A includes a main surface 51a (first main surface) and a main surface 51b (second main surface) opposite each other, and the IDT electrodes 11 to 17 and the reflecting electrodes 41 and 42 are disposed at the main surface 51a. For example, lithium tantalate (LiTaO₃) may be used for the piezoelectric layer 51A. The film thickness of the piezoelectric layer 51A is, for example, about 900 nm, within manufacturing or measurement tolerances.

The metal layer 52A is coupled with the main surface 51b of the piezoelectric layer 51A. As illustrated in FIG. 7A, in plan view of the main surfaces 51a and 51b of the piezoelectric layer 51A, the metal layer 52A includes multiple separate metal layers 520. As viewed in plan, each of the multiple metal layers 520 overlaps one of the IDT electrodes 11 to 17 and the reflecting electrodes 41 and 42. For example, a first metal layer, which is one of the multiple metal layers 520, overlaps the IDT electrode 11 in plan view, and a second metal layer, which is another one of the multiple metal layers 520, overlaps the IDT electrode 12 in plan view. The first metal layer and the second metal layer are separate. In plan view, the metal layer 52A does not overlap inter-IDT-electrode area in which no electrode finger is disposed and that is between the IDT electrode 11 (first IDT electrode) and the IDT electrode 12 (second IDT electrode). In other words, the metal layer 52A does not overlap an inter-IDT-electrode area between one of the multiple electrode fingers included in the first IDT electrode and located closest to the second IDT electrode, and one of the multiple electrode fingers included in the second IDT electrode and located closest to the first IDT electrode.

This structure can reduce electric field coupling between the electrode fingers in the IDT electrode 11 and the electrode fingers in the IDT electrode 12 through the metal layer 52A. Thus, the acoustic wave filter 1A can reduce degradation of attenuation characteristics.

For example, titanium (Ti) may be used for the metal layer 52A. The film thickness of the metal layer 52A is, for example, about 50 nm, within manufacturing or measurement tolerances. The metal layer 52A may include an alloy including multiple metal materials, or a multilayer body including multiple layers formed from different metal materials. In addition, an adhesive layer may be interposed between the metal layer 52A and the piezoelectric layer 51A to ensure strength to bond these layers.

As viewed in plan, each of the multiple metal layers 520 does not have to overlap the entire area of any one of the IDT electrodes 11 to 17 and the reflecting electrodes 41 and 42, and may overlap at least a portion of any one of the electrodes.

The metal layer 52A does not have to include multiple separate metal layers 520, and may include slit portions not including a metal film. In this structure, the above slit portions overlap the inter-IDT-electrode areas as viewed in plan.

This structure can reduce electric field coupling between two adjacent IDT electrodes through the metal layer 52A. The acoustic wave filter 1A can thus reduce degradation of attenuation characteristics.

A space between the multiple metal layers of the metal layer 52A is filled with the same material as that of the piezoelectric layer 51A. Alternatively, a space between the multiple metal layers of the metal layer 52A may be filled with the same material as that of the low-acoustic-velocity layer 53.

The low-acoustic-velocity layer 53, the high-acoustic-velocity layer 54, and the support substrate 55 according to the present modification example have the same structures as the low-acoustic-velocity layer 53, the high-acoustic-velocity layer 54, and the support substrate 55 according to the above-described example embodiment, and thus are not described.

An acoustic wave filter 1B according to a second modification example of an example embodiment of the present disclosure is described now. The acoustic wave filter 1B according to the present modification example is an example of an acoustic wave device, and includes a longitudinally coupled resonator 10B, series-arm resonators 21, 22, and 23, and parallel-arm resonators 31, 32, and 33. The acoustic wave filter 1B according to the present modification example differs from the acoustic wave filter 1 according to the above-described example embodiment in terms of the structure of a multilayer substrate 50B. Hereafter, the acoustic wave filter 1B according to the present modification example is mainly described in terms of a different structure, and descriptions of the same components as those in the acoustic wave filter 1 according to the above-described example embodiment are omitted.

The longitudinally coupled resonator 10B includes seven acoustic wave resonators. Each of the seven acoustic wave resonators includes IDT electrodes disposed at the multilayer substrate 50B. The structures of the IDT electrodes and reflecting electrodes included in the seven acoustic wave resonators are the same as the structures of the IDT electrodes and the reflecting electrodes included in the longitudinally coupled resonator 10, and the electrode parameters are the same as those listed in Table 1.

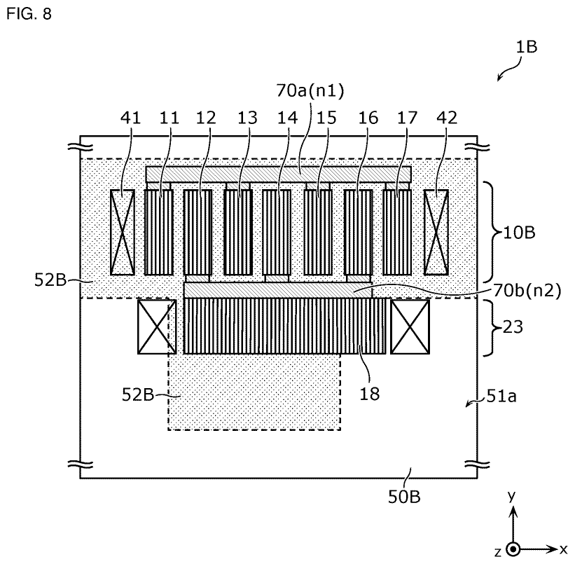

FIG. 8 is a plan view of the acoustic wave filter 1B according to the second modification example of the example embodiment. FIG. 8 is a diagram of the main surface 51a (first main surface) of the piezoelectric layer 51 included in the acoustic wave filter 1B, viewed from the side in the positive z-axis direction. FIG. 8 also illustrates a metal layer 52B coupled with a main surface 51b (second main surface) of the piezoelectric layer 51, as viewed through the piezoelectric layer 51.

As illustrated in FIG. 8, the longitudinally coupled resonator 10B includes the multilayer substrate 50B, the multiple IDT electrodes 11 to 17, and the reflecting electrodes 41 and 42. The longitudinally coupled resonator 10B does not have to include the reflecting electrodes 41 and 42. Unlike in FIG. 2 in which the electrode fingers and reflecting electrode fingers are drawn in detail, FIG. 8 is a diagram of the IDT electrodes 11 to 17 and the reflecting electrodes 41 and 42 with simplified marks.

As illustrated in FIG. 8, the series-arm resonator 23 includes an IDT electrode 18 (third IDT electrode) disposed at the multilayer substrate 50B.

As illustrated in FIG. 8, busbar electrodes of the IDT electrodes 11, 13, 15, and 17 located in the positive y-axis direction are connected in common to a connection wire 70a (corresponding to an input-output node n1) serving as a hot terminal. Busbar electrodes of the IDT electrodes 12, 14, and 16 located in the negative y-axis direction are connected in common to a connection wire 70b (corresponding to an input-output node n2) serving as a hot terminal. In FIG. 8, the ground connection structure in the IDT electrodes 11 to 17 is not illustrated. The IDT electrode 18 is connected to the connection wire 70b (corresponding to the input-output node n2).

The multilayer substrate 50B is an example of a piezoelectric substrate having piezoelectricity, and includes a piezoelectric layer 51, a metal layer 52B, a low-acoustic-velocity layer 53, a high-acoustic-velocity layer 54, and a support substrate 55.

The piezoelectric layer 51 includes a main surface 51a (first main surface) and a main surface 51b (second main surface) opposite each other, and the IDT electrodes 11 to 18 and the reflecting electrodes 41 and 42 are disposed at the main surface 51a.

The metal layer 52B is coupled with the main surface 51b of the piezoelectric layer 51. As illustrated in FIG. 8, in plan view of the main surfaces 51a and 51b of the piezoelectric layer 51, the metal layer 52B overlaps the multiple IDT electrodes 11 to 17, and overlaps at least a portion of the IDT electrode 18 in the series-arm resonator 23.

In this structure, the metal layer 52B overlaps both the longitudinally coupled resonator 10B and the series-arm resonator 23 included in the acoustic wave filter 1B, and thus, the acoustic wave filter 1B has improved thermal uniformity. Thus, temperature-dependent frequency shifts of the longitudinally coupled resonator 10B and the series-arm resonator 23 are equalized, and frequency-temperature characteristics of the acoustic wave filter 1B can be adjusted with high precision.

For example, titanium (Ti) may be used for the metal layer 52B. The film thickness of the metal layer 52B is, for example, 50 nm. The metal layer 52B may include an alloy including multiple metal materials, or a multilayer body including multiple layers including different metal materials. In addition, an adhesive layer may be interposed between the metal layer 52B and the piezoelectric layer 51 to ensure strength to bond these layers.

In addition to the longitudinally coupled resonator 10B and the series-arm resonator 23, the metal layer 52B may also overlap IDT electrodes included in another acoustic wave resonator as viewed in plan.

As described above, the acoustic wave filter 1 according to the present example embodiment includes the longitudinally coupled resonator 10 including the multilayer substrate 50 and the multiple IDT electrodes 11 to 17. The multilayer substrate 50 includes the piezoelectric layer 51 including the main surfaces 51a and 51b opposite each other, the multiple IDT electrodes 11 to 17 being disposed at the main surface 51a, and the metal layer 52 coupled with the main surface 51b of the piezoelectric layer 51. Each of the multiple IDT electrodes 11 to 17 includes multiple electrode fingers parallel or substantially parallel to each other. In plan view of the main surfaces 51a and 51b, the metal layer 52 extends across adjacent ones of the plurality of electrode fingers included in one of the multiple IDT electrodes 11 to 17.

In this structure, the metal layer 52 coupled with the main surface 51b of the piezoelectric layer 51 is capacitively coupled with the multiple electrode fingers included in each IDT electrode, and the capacitive coupling provides a charge path from each electrode finger to the metal layer 52. The charge path reduces unused electric field coupling that would occur between two adjacent IDT electrodes. The acoustic wave filter 1 can thus reduce degradation of attenuation characteristics.

For example, in the acoustic wave filter 1A according to the first modification example, the multiple IDT electrodes 11 to 17 include IDT electrodes 11 and 12 adjacent to each other in a direction perpendicular to the extension direction of the multiple electrode fingers. In plan view of the main surfaces 51a and 51b, the metal layer 52A does not overlap the inter-IDT-electrode area between one of the multiple electrode fingers included in the IDT electrode 11 and located closest to the IDT electrode 12, and one of the multiple electrode fingers included in the IDT electrode 12 and located closest to the IDT electrode 11.

This structure can reduce electric field coupling between the electrode fingers in the IDT electrode 11 and the electrode fingers in the IDT electrode 12 through the metal layer 52A. Thus, the acoustic wave filter 1A can reduce degradation of attenuation characteristics.

For example, in the acoustic wave filter 1A, the metal layer 52A includes slit portions not including a metal film. In plan view of the main surfaces 51a and 51b, the slit portions overlap the inter-IDT-electrode areas.

This structure can reduce electric field coupling between two adjacent IDT electrodes through the metal layer 52A. The acoustic wave filter 1A can thus reduce degradation of attenuation characteristics.

For example, in the acoustic wave filter 1A, the metal layer 52A includes multiple separate metal layers 520, and in plan view of the main surfaces 51a and 51b, one of the multiple metal layers 520 overlaps the IDT electrode 11, and another one of the multiple metal layers 520 overlaps the IDT electrode 12.

This structure can reduce electric field coupling between two adjacent IDT electrodes through the metal layer 52A. The acoustic wave filter 1A can thus reduce degradation of attenuation characteristics.

For example, in the acoustic wave filter 1, in plan view of the main surfaces 51a and 51b, the metal layer 52 overlaps the entire areas of the multiple IDT electrodes 11 to 17.

In this structure, a charge path from each electrode finger included in the IDT electrode to the metal layer 52 is provided, and reduces unused electric field coupling that would occur between two adjacent IDT electrodes. The acoustic wave filter 1 can thus reduce degradation of attenuation characteristics.

For example, the acoustic wave filter 1B according to the second modification example further includes a series-arm resonator 23 connected to the longitudinally coupled resonator 10B, and the series-arm resonator 23 includes an IDT electrode 18 disposed at the piezoelectric layer 51. In plan view of the main surfaces 51a and 51b, the metal layer 52B overlaps at least a portion of the IDT electrode 18.

In this structure, the metal layer 52B overlaps both the longitudinally coupled resonator 10B and the series-arm resonator 23, and thus, the acoustic wave filter 1B has improved thermal uniformity. Thus, temperature-dependent frequency shifts of the longitudinally coupled resonator 10B and the series-arm resonator 23 are equalized, and frequency-temperature characteristics of the acoustic wave filter 1B can be adjusted with high precision.

For example, in the acoustic wave filter 1, the metal layer 52 is connected to the ground.

The acoustic wave filter 1 with this structure can release unused electric field that occurs in the piezoelectric layer 51 to the ground through the metal layer 52, and thus can reduce degradation of attenuation characteristics.

For example, in the acoustic wave filter 1, the multilayer substrate 50 further includes a support substrate 55, and the support substrate 55, the metal layer 52, and the piezoelectric layer 51 are laminated in this order.

For example, in the acoustic wave filter 1, the multilayer substrate 50 further includes a low-acoustic-velocity layer 53 disposed between the metal layer 52 and the support substrate 55 and that allows bulk waves to propagate therethrough at a lower acoustic velocity than bulk waves that propagate through the piezoelectric layer 51, and a high-acoustic-velocity layer 54 disposed between the low-acoustic-velocity layer 53 and the support substrate 55 and that allows bulk waves to propagate therethrough at a higher acoustic velocity than acoustic waves that propagate through the piezoelectric layer 51.

This structure can reduce leakage of surface acoustic wave energy out of the piezoelectric layer 51. The acoustic wave filter can significantly increase q-values, in resonant frequency and antiresonant frequency, of an acoustic wave resonator included in the acoustic wave filter, and has a reduced insertion loss.

Acoustic wave devices according to example embodiments and modification examples of example embodiments of the present invention have been described above, but the present invention is not limited to the above example embodiments and modification examples. Another example embodiment including a combination of any components in the example embodiments and the modification examples, and a modification example obtained by modifying any of the example embodiments and the modification examples within the scope not departing from the gist of the present invention and conceivable by persons skilled in the art are also included in the present invention.

Example embodiments of the present invention are widely applicable to communication devices, such as mobile phones, as acoustic wave devices included in front end modules.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a longitudinally coupled resonator including a piezoelectric substrate and a plurality of interdigital transducer (IDT) electrodes; wherein
the piezoelectric substrate includes:
a piezoelectric layer including a first main surface and a second main surface opposite each other, the plurality of IDT electrodes being located at the first main surface; and
a metal layer coupled with the second main surface of the piezoelectric layer;
each of the plurality of IDT electrodes includes a plurality of electrode fingers parallel or substantially parallel to each other; and
in plan view of the first main surface and the second main surface, the metal layer extends across adjacent ones of the plurality of electrode fingers included in one of the plurality of IDT electrodes.

2. The acoustic wave device according to claim 1, wherein
the plurality of IDT electrodes include a first IDT electrode and a second IDT electrode adjacent to each other in a direction perpendicular to an extension direction of the plurality of electrode fingers; and
in plan view of the first main surface and the second main surface, the metal layer does not overlap an inter-IDT-electrode area between one of the plurality of electrode fingers included in the first IDT electrode and located closest to the second IDT electrode, and one of the plurality of electrode fingers included in the second IDT electrode and located closest to the first IDT electrode.

3. The acoustic wave device according to claim 2, wherein
the metal layer includes a slit portion in which no metal film is included; and
in plan view of the first main surface and the second main surface, the slit portion overlaps the inter-IDT-electrode area.

4. The acoustic wave device according to claim 2, wherein
the metal layer includes a first metal layer and a second metal layer that are separate from each other; and
in plan view of the first main surface and the second main surface, the first metal layer overlaps the first IDT electrode, and the second metal layer overlaps the second IDT electrode.

5. The acoustic wave device according to claim 1, wherein, in plan view of the first main surface and the second main surface, the metal layer overlaps entire areas of the plurality of IDT electrodes.

6. The acoustic wave device according to claim 1, further comprising:
an acoustic wave resonator connected to the longitudinally coupled resonator; wherein
the acoustic wave resonator includes a third IDT electrode located at the piezoelectric layer; and
in plan view of the first main surface and the second main surface, the metal layer overlaps at least a portion of the third IDT electrode.

7. The acoustic wave device according to claim 1, wherein the metal layer is connected to a ground.

8. The acoustic wave device according to claim 1, wherein
the piezoelectric substrate further includes a support substrate; and
the support substrate, the metal layer, and the piezoelectric layer are laminated in order of the support substrate, the metal layer, and the piezoelectric layer.

9. The acoustic wave device according to claim 8, wherein the piezoelectric substrate further includes:
a low-acoustic-velocity layer between the metal layer and the support substrate and that allows bulk waves to propagate therethrough at a lower acoustic velocity than bulk waves that propagate through the piezoelectric layer; and
a high-acoustic-velocity layer between the low-acoustic-velocity layer and the support substrate and that allows bulk waves to propagate therethrough at a higher acoustic velocity than acoustic waves that propagate through the piezoelectric layer.

10. The acoustic wave device according to claim 1, wherein the longitudinally coupled resonator includes reflector electrodes.

11. The acoustic wave device according to claim 1, further comprising an acoustic wave filter including a series arm resonator including an IDT electrode; wherein
the metal layer overlaps at least a portion of the IDT electrode of the series arm resonator.

12. The acoustic wave device according to claim 1, wherein the metal layer includes titanium.

13. The acoustic wave device according to claim 1, wherein the metal layer has a thickness of about 50 nm.

14. The acoustic wave device according to claim 1, wherein the metal layer includes an alloy of multiple metals.

15. The acoustic wave device according to claim 1, wherein the metal layer includes multiple layers including different metal materials.

16. The acoustic wave device according to claim 1, further comprising an adhesive layer between the metal layer and the piezoelectric layer.

17. The acoustic wave device according to claim 1, further comprising a series arm resonator and another acoustic wave resonator; wherein
the metal layer overlaps IDT electrodes included in the another acoustic wave resonator.

18. The acoustic wave device according to claim 1, wherein the metal layer is capacitively coupled with the plurality of electrode fingers to define a charge path from each of the plurality of electrode fingers to the metal layer.

19. The acoustic wave device according to claim 1, further comprising:
a series arm resonator connected to the longitudinally coupled resonator; wherein
the series arm resonator includes an IDT electrode at the piezoelectric layer; and
the metal layer overlaps at least a portion of the IDT electrode of the series arm resonator.

20. The acoustic wave device according to claim 1, further comprising:
a series arm resonator connected to the longitudinally coupled resonator; wherein
the metal layer overlaps both the longitudinally coupled resonator and the series arm resonator.
